(19) United States
(12) Patent Application Publication
(10) Pub. No.: US 2026/0118418 A1
(43) Pub. Date: Apr. 30, 2026

(54) SEMICONDUCTOR DEVICE

(71) Applicant: Samsung Electronics Co., Ltd., Suwon-si (KR)

(72) Inventors: Yoseop LIM, Suwon-si (KR); Kiok KIM, Suwon-si (KR)

(73) Assignee: Samsung Electronics Co., Ltd., Suwon-si (KR)

(21) Appl. No.: 19/008,962

(22) Filed: Jan. 3, 2025

(30) Foreign Application Priority Data
Jul. 9, 2024 (KR) 10-2024-0090381

(51) Int. Cl. G01R 31/28; H01L 25/065

(52) U.S. Cl. CPC G01R 31/2896; G01R 31/2853; G01R 31/2884; H10W 90/00

(57) ABSTRACT

A semiconductor device includes a plurality of test circuits connected between a test input pin and a test output pin, and a TAP controller connected to a plurality of test control pins and configured to define a data transmission path between the test input pin and the test output pin in response to test control signals received by the plurality of test control pins, the data transmission path including at least one of the plurality of test circuits.

### CROSS-REFERENCE TO RELATED APPLICATION(S)

This application claims the benefit and priority under 35 USC 119(a) of Korean Patent Application No. 10-2024-0090381 filed on Jul. 9, 2024 in the Korean Intellectual Property Office, the entire disclosure of which is incorporated herein by reference for all purposes.

### BACKGROUND

The present inventive concepts relate to semiconductor devices.

Semiconductor devices are connected to other semiconductor devices to provide various functions, and the semiconductor devices may be stacked with substrates and/or other semiconductor devices. As the structure of packages including semiconductor devices becomes more diverse, defects such as cracks may occur in the semiconductor devices due to pressure or the like applied during the process of connecting the semiconductor devices to the substrate and/or other semiconductor devices. Therefore, a method is required that may efficiently determine whether crack defects occur in semiconductor devices at various process stages.

### SUMMARY

Some example embodiments provide a semiconductor device in which whether cracking has occurred and the location in which cracking has occurred may be rapidly verified by utilizing a Test Access Port (TAP) controller and a test data register mounted on the semiconductor device for performing testing.

According to some example embodiments, a semiconductor device includes a plurality of test circuits connected in series between a test input pin and a test output pin; and a Test Access Port (TAP) controller connected to a plurality of test control pins and configured to control the plurality of test circuits in response to test control signals received by the plurality of test control pins. Each of the plurality of test circuits includes a test data register. At least one test circuit among the plurality of test circuits includes test wiring including test patterns at different heights in a first direction in a Back-End-Of-Line (BEOL) region and test vias connecting the test patterns. The TAP controller is configured to control the plurality of test circuits based on the test control signals so that test output data corresponding to test input data input to the test input pin is output to the test output pin.

According to some example embodiments, a semiconductor package includes a package substrate having wiring patterns; and a plurality of semiconductor devices on an upper surface of the package substrate. At least one semiconductor device among the plurality of semiconductor devices includes a plurality of test control pins, a test input pin, and a test output pin connectable to a JTAG interface, and the plurality of test control pins, the test input pin and the test output pin are electrically connected to one of the wiring patterns of the package substrate. The at least one semiconductor device includes a plurality of test data registers connected between the test input pin and the test output pin, and a test wiring connected between at least two test data registers among the plurality of test data registers and in a Back-End-Of-Line (BEOL) region.

According to some example embodiments, a semiconductor device includes a plurality of test circuits connected between a test input pin and a test output pin; and a TAP controller connected to a plurality of test control pins and configured to define a data transmission path between the test input pin and the test output pin in response to test control signals received by the plurality of test control pins, the data transmission path including at least one of the plurality of test circuits.

### BRIEF DESCRIPTION OF DRAWINGS

The above and other aspects, features, and advantages of the present inventive concepts will be more clearly understood from the following detailed description, taken in conjunction with the accompanying drawings, in which:

FIGS. 1A and 1B are schematic drawings of a semiconductor package including a semiconductor device according to some example embodiments;

FIGS. 2A and 2B are schematic drawings of a semiconductor package including a semiconductor device according to some example embodiments;

FIG. 3 is a schematic drawing of a semiconductor device according to some example embodiments;

FIG. 4 is a schematic drawing of a semiconductor device according to some example embodiments;

FIGS. 5 to 7 are drawings illustrating a crack detection operation in a semiconductor device according to some example embodiments;

FIGS. 8 and 9 are schematic drawings of a semiconductor device according to some example embodiments;

FIGS. 10 to 12 are drawings illustrating a crack detection operation in a semiconductor device according to some example embodiments;

FIGS. 13 and 14 are drawings illustrating a crack detection operation in a semiconductor device according to some example embodiments;

FIG. 15 is a schematic drawing of a semiconductor device according to some example embodiments; and

FIG. 16 is a flowchart illustrating a test operation in a semiconductor device according to some example embodiments.

### DETAILED DESCRIPTION

Hereinafter, some example embodiments will be described with reference to the accompanying drawings.

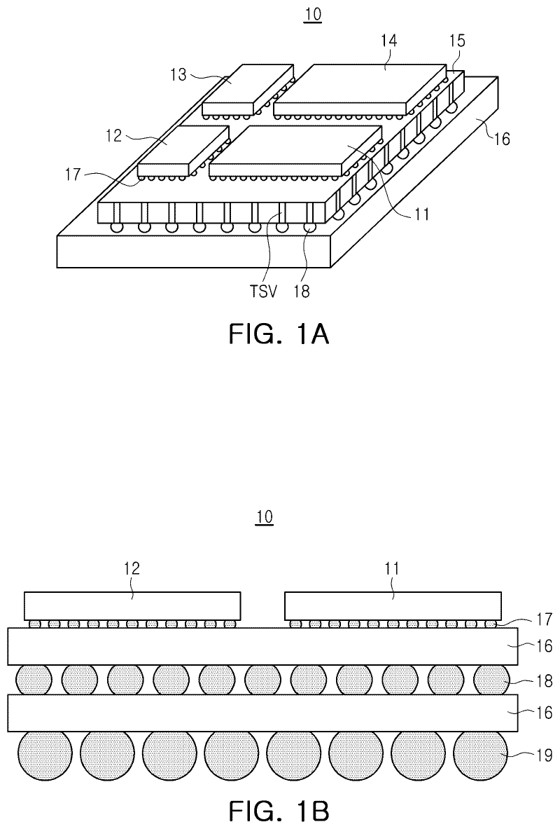

FIGS. 1A and 1B are drawings simply illustrating a semiconductor package including a semiconductor device according to some example embodiments.

A semiconductor package 10 according to some example embodiments illustrated in FIGS. 1A and 1B may be a 2.5D structure package. Referring to FIGS. 1A and 1B, the semiconductor package 10 may include a plurality of semiconductor devices 11 to 14, an interposer substrate 15, a package substrate 16, and the like. At least some of the plurality of semiconductor devices 11 to 14 may execute different functions and may be mounted on the interposer substrate 15 by a plurality of micro bumps 17.

The interposer substrate 15 may be mounted on the package substrate 16 by a plurality of solder bumps 18. Inside the interposer substrate 15, via structures (TSV) connected to a plurality of micro bumps 17 and a plurality of solder bumps 18 are formed, and in some example embodiments, the via structures TSV may be through silicon vias. For example, the interposer substrate 15 may provide a passage for electrical connection between at least some of the plurality of semiconductor devices 11 to 14. Meanwhile, in the package substrate 16, wiring patterns electrically connected to the semiconductor devices 11 to 14 are formed through a plurality of micro bumps 17 and a plurality of solder bumps 18, and solder balls 19 may be disposed on the lower surface of the package substrate 16.

In a semiconductor package 10 such as some example embodiments illustrated in FIGS. 1A and 1B, during a process of bonding the semiconductor devices 11 to 14 to the interposer substrate 15, a process of bonding the interposer substrate 15 to which the semiconductor devices 11 to 14 are bonded, to the package substrate 16, and the like, a defect may occur in at least one of the semiconductor devices 11 to 14 due to the pressure applied to the semiconductor devices 11 to 14. For example, cracking may occur in at least one of the semiconductor devices 11 to 14 due to bonding stress occurring in the bonding process.

In some example embodiments, whether a defect such as cracking occurs may be accurately determined by using a Test Access Port (TAP) controller that is mounted on a semiconductor device and connectable to a Joint Test Action Group (JTAG) interface, and test circuits controlled by the TAP controller. For example, a TAP controller that is connectable to a JTAG interface is mounted on at least one of the semiconductor devices 11 to 14, and the TAP controller may be connected to a plurality of test control pins. Meanwhile, the TAP controller controls a plurality of test circuits, and the plurality of test circuits may be connected between a test input pin and a test output pin. The plurality of test control pins, the test input pin, and the test output pin may be electrically connected to some of the wiring patterns of the package substrate 16 through the interposer substrate 15.

Each of the plurality of test circuits may include a test data register, and at least one of the plurality of test circuits may include a test wiring. The TAP controller may control the test data register of each of the plurality of test circuits to transmit test data from the test input pin to the test output pin. In a case in which a defect such as cracking occurs in the test wiring, the test data may not be detected successfully at the test output pin. Therefore, whether a defect such as cracking occurs may be quickly and/or effectively detected.

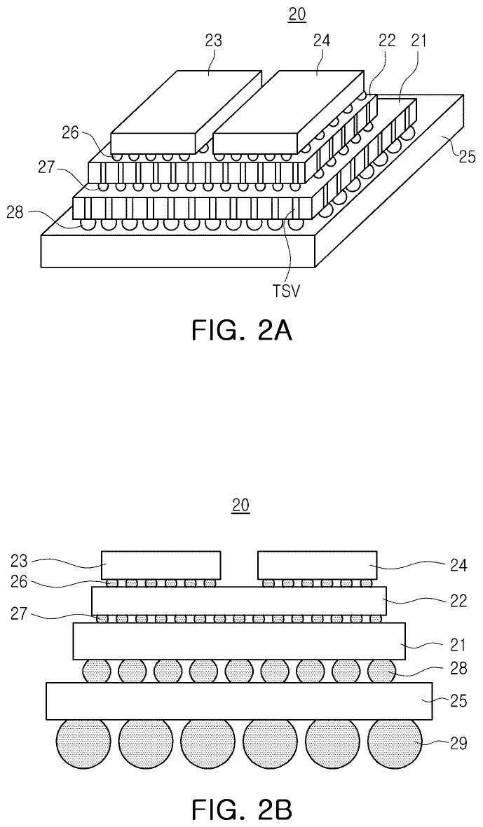

FIGS. 2A and 2B are schematic drawings of a semiconductor package including a semiconductor device according to some example embodiments.

A semiconductor package 20 according to some example embodiments illustrated in FIGS. 2A and 2B may be a 3D structure package. Referring to FIGS. 2A and 2B, the semiconductor package 20 may include a plurality of semiconductor devices 21 to 24, a package substrate 25, and the like. At least some of the plurality of semiconductor devices 21 to 24 may be stacked and connected to each other by a plurality of micro bumps 26 and 27.

Referring to FIGS. 2A and 2B, among the plurality of semiconductor devices 21 to 24, a first semiconductor device 21 is directly mounted on the package substrate 25 by a plurality of solder bumps 28, and the solder bumps 28 may be electrically connected to solder balls 29 on the lower surface of the package substrate 25. Meanwhile, the second to fourth semiconductor devices 22 to 24 are stacked on the first semiconductor device 21 by a plurality of micro bumps 26 and 27, and the first semiconductor device 21 and the second semiconductor device 22 may include via structures (TSV) for connection between the semiconductor devices 21 to 24.

Similar to some example embodiments described above with reference to FIGS. 1A and 1B, in some example embodiments illustrated in FIGS. 2A and 2B, a defect such as cracking may occur in at least one of the semiconductor devices 21 to 24 during the process of stacking the semiconductor devices 21 to 24 on each other, the process of bonding the semiconductor devices 21 to 24 to the package substrate 25, or the like. In some example embodiments, by utilizing the JTAG interface mounted on each of the semiconductor devices 21 to 24, whether or not a defect occurs in each of the semiconductor devices 21 to 24 may be accurately verified.

For example, each of the semiconductor devices 21 to 24 includes a TAP controller connectable to the JTAG interface, and test circuits controlled by the TAP controller, and the test circuits may be connected between the test input pin and the test output pin. The TAP controller is connected to a plurality of test control pins, and the plurality of test control pins, the test input pin, and the test output pin may be electrically connected to some of the wiring patterns of the package substrate 25.

At least one of the test circuits may include a test wiring including a plurality of test patterns and a plurality of test vias. In some example embodiments, by comparing test input data input to the test input pin with test output data output to the test output pin through the JTAG interface, whether or not cracking is present in the test wiring may be determined.

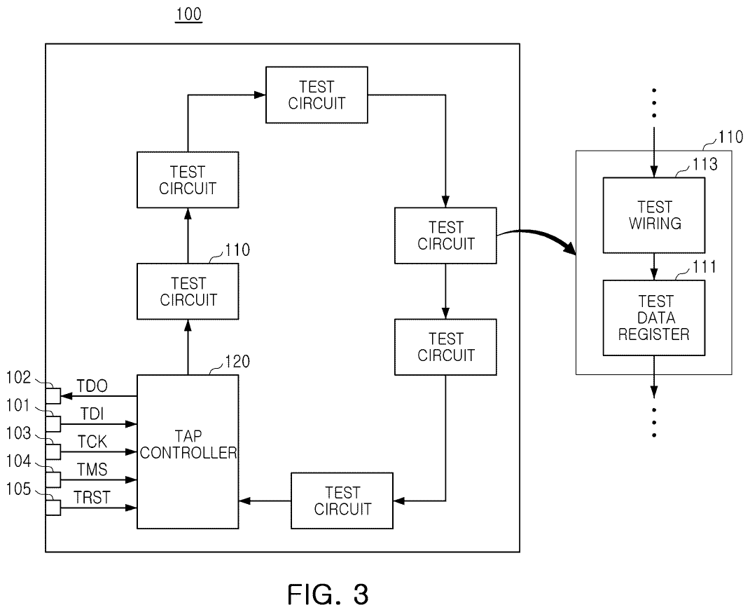

FIG. 3 is a drawing simply illustrating a semiconductor device according to some example embodiments.

Referring to FIG. 3, a semiconductor device 100 according to some example embodiments may include a plurality of test circuits 110 a TAP controller 120, and the like. The TAP controller 120 is connected to a test input pin 101, a test output pin 102, and a plurality of test control pins 103 to 105, and may control a plurality of test circuits 110 in response to test control signals TCK, TMS and TRST received through the plurality of test control pins 103 to 105.

For example, the TAP controller 120 may be connected to external test equipment and the like through a JTAG interface, and may receive test control signals TCK, TMS and TRST. In some example embodiments illustrated in FIG. 3, the TAP controller 120 may receive a test clock signal TCK, a test mode signal TMS, and a test reset signal TRST through a plurality of test control pins 103 to 105, but depending on some example embodiments, the test reset signal TRST and the test control pin 105 for receiving the same may be omitted.

A plurality of test circuits 110 are connected in series with each other, and may transmit test input data TDI input to the test input pin 101 to the test output pin 102. Accordingly, test output data TDO may be output to the test output pin 102. According to some example embodiments, a plurality of test circuits 110 may be connected in series between a test input pin 101 and a test output pin 102.

In some example embodiments, a plurality of test circuits 110 may be disposed along a boundary of a semiconductor device 100 for boundary scan. In this case, the plurality of test circuits 110 may be connected to a plurality of pins other than the test input pin 101, the test output pin 102, and the plurality of test control pins 103 to 105. The core logic of the semiconductor device 100 may be connected to the plurality of pins through the plurality of test circuits 110.

In some example embodiments illustrated in FIG. 3, each of the plurality of test circuits 110 may include a test data register 111. The test data register 111 is controlled by the TAP controller 120 and may store or export data received from the test input pin 101 or the test data register 111 of previous test circuit 110.

The test data register 111 may include a first unit register and a second unit register that are operated by different control signals output by the TAP controller 120. For example, the first unit register may store data received from the test input pin 101 or the preceding test circuit 110 in response to the first control signal output by the TAP controller 120. For example, the second unit register may output data stored in the first unit register to the next test circuit 110 or the test output pin 102 in response to the second control signal output by the TAP controller 120.

Referring to FIG. 3, at least one test circuit among the plurality of test circuits 110 may include a test wiring 113 connected to a test data register 111. The test wiring 113 is connected to an input terminal or an output terminal of the test data register 111, and thus, the test wiring 113 may be disposed between a pair of test data registers 111 within the semiconductor device 100.

The test wiring 113 may include a plurality of test patterns and a plurality of test vias, and the plurality of test vias may connect at least some of the test patterns disposed at different heights among the plurality of test patterns to each other. In some example embodiments, the test wiring 113 may be placed in a Back-End-Of-Line (BEOL) region of the semiconductor device 100. The semiconductor device 100 may include a semiconductor substrate including a semiconductor material, a Front-End-Of-Line (FEOL) region defined on the semiconductor substrate and in which semiconductor elements such as transistors and the like are disposed, a BEOL region disposed on the FEOL region, and the like. According to some example embodiments, the test wiring may be disposed only in the BEOL region, not the FEOL region.

The test wiring 113 may be inserted for the use of determining whether a defect occurs in a bonding process, such as when the semiconductor device 100 is mounted on an interposer substrate, a package substrate, or the like, or when the semiconductor device 100 is stacked with another semiconductor device. For example, the test wiring 113 may be used to determine a defect, such as cracking, that occurs in another process performed after the semiconductor device 100 is manufactured.

For determining a defect, a test input pin 101, a test output pin 102, and a plurality of test control pins 103 to 105 may be connected to a JTAG interface, and test input data may be input to the test input pin 101. For example, the test input data may be sequence data in which 0 or 1 is sequentially input.

TAP controller 120 may control multiple test circuits 110 in response to test control signals TCK, TMS and TRST input to multiple test control pins 103 to 105. For example, TAP controller 120 may control test data register 111 included in each of multiple test circuits 110 to capture or update test input data in response to test control signals TCK, TMS and TRST.

In the case in which a defect occurs in test wiring 113 in a bonding process or the like of a semiconductor device 100, test output data TDO detected at a test output pin 102 may not match test input data TDI. For example, in a bonding process of a semiconductor device 100, or the like, cracking may occur in at least one of a plurality of test vias and a plurality of test patterns included in a test wiring 113, resulting in a defect such as an open or a short. If such a defect occurs, test input data TDI input to a test input pin 101 may not be output from the test data register 111 at an accurate time, for example, at the toggle time of a test clock signal TCK. Therefore, based on whether the test output data TDO output to the test output pin 102 at a given point in time matches the test input data TDI, whether a defect such as cracking is present in the test wiring 113 may be determined.

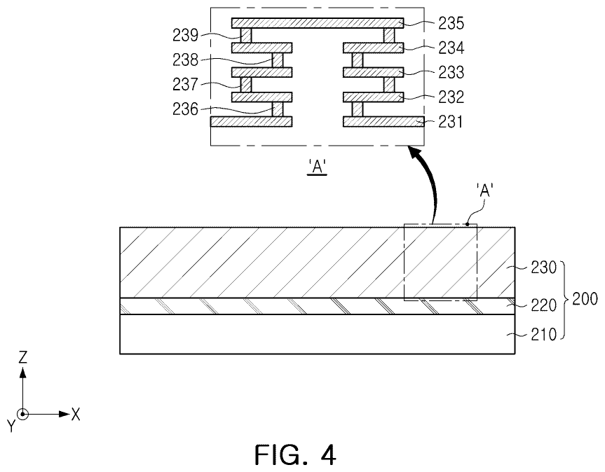

FIG. 4 is a simple drawing illustrating a semiconductor device according to some example embodiments.

Referring to FIG. 4, a semiconductor device 200 according to some example embodiments may include a semiconductor substrate 210, a FEOL region 220, a BEOL region 230, and the like. The FEOL region 220 may be disposed on the semiconductor substrate 210 in a first direction (Z-axis direction), and the BEOL region 230 may be disposed on the FEOL region 220 in the first direction.

The FEOL region 220 may be an area where a FEOL process for forming semiconductor elements such as transistors on the semiconductor substrate 210 is executed. Meanwhile, the BEOL region 230 may be a region where a BEOL process is performed to form wirings for connecting semiconductor elements formed in the FEOL region 220 to each other and input/output pins connected to the wirings.

As in some example embodiments described above with reference to FIG. 3, most of the components of the test data registers 111 included in the semiconductor device 100 may be placed in the FEOL region 220. Therefore, if each of the test circuits 110 is configured to include only a test data register 111, whether a defect such as cracking occurs may be determined by controlling the test data register 111 of each of the test circuits 110 with the TAP controller 120, but a defect that may occur in the wirings included in the BEOL region 230 may not be determined.

In some example embodiments, as described above with reference to FIG. 3, at least one of the test circuits 110 may include a test wiring 113 connected to the test data register 111. Referring to FIG. 4, the test wiring may be placed in the ‘A’ area of the BEOL region 230. The test wiring includes a plurality of test patterns 231 to 235 and a plurality of test vias 236 to 239, and the test patterns 231 to 235 disposed at different heights in the first direction may be connected to each other by the test vias 236 to 239. In this manner, by configuring the test wiring with the test patterns 231 to 235 and the test vias 236 to 239 of the BEOL region 230 and connecting the test wiring to the test data register, whether a defect occurs in the BEOL region 230 of the semiconductor device 200 may be effectively monitored.

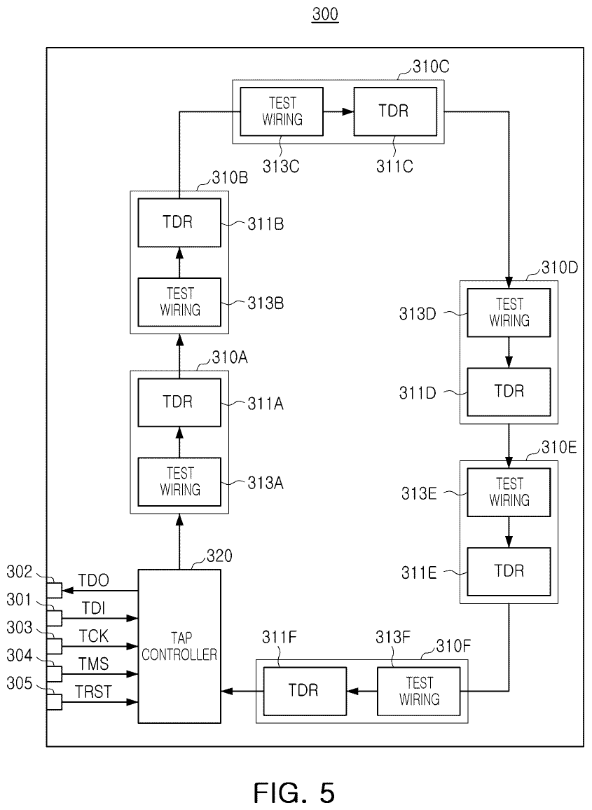

FIGS. 5 to 7 are drawings provided to illustrate a crack detection operation in a semiconductor device according to some example embodiments.

First, referring to FIG. 5, a semiconductor device 300 according to some example embodiments may include a plurality of test circuits 310A to 310F, a TAP controller 320, and the like. The TAP controller 320 is connected to a test input pin 301, a test output pin 302, and a plurality of test control pins 303 to 305, and may control the plurality of test circuits 310A to 310F in response to test control signals TCK, TMS and TRST received through the plurality of test control pins 303 to 305. The TAP controller 320 is connected to external test equipment and the like through a JTAG interface, and may receive test control signals TCK, TMS and TRST.

In some example embodiments illustrated in FIG. 5, the plurality of test circuits 310A to 310F may include test data registers 311A to 311F and test wirings 313A to 313F, respectively. Referring to FIG. 5, the test wirings 313A to 313F are illustrated as being disposed in front of the test data registers 311A to 311F in the plurality of test circuits 310A to 310F, but the test wirings 313A to 313F may also be disposed in the rear of the test data registers 311A to 311F, respectively.

The plurality of test circuits 310A to 310F may be connected in series with each other, and the test input data TDI input to the test input pin 301 may be transmitted to the test output pin 302 through the plurality of test circuits 310A to 310F. If the test output data TDO output to the test output pin 302 at a given point in time matches the test input data TDI, it may be determined that there is no defect such as cracking in the semiconductor device 300. Test data registers 311A to 311F are controlled by the TAP controller 320 and may store or output data in response to a command transmitted by the TAP controller 320.

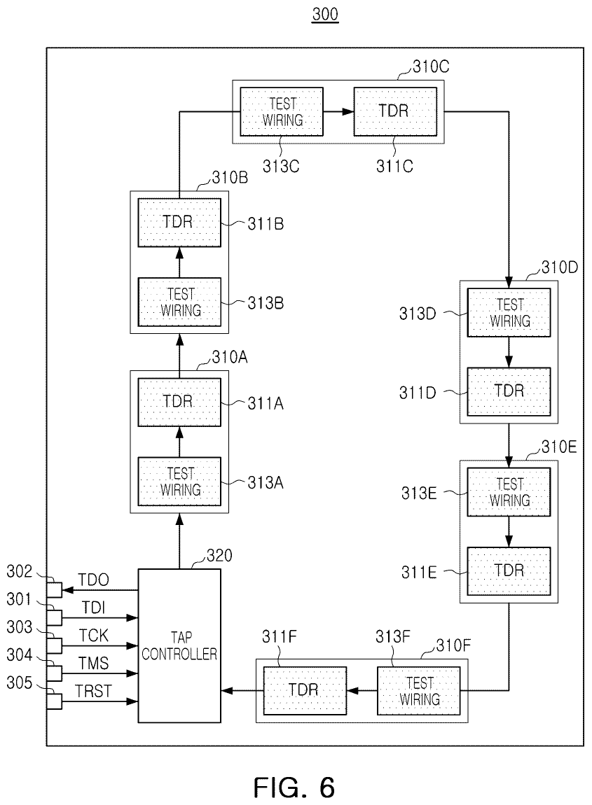

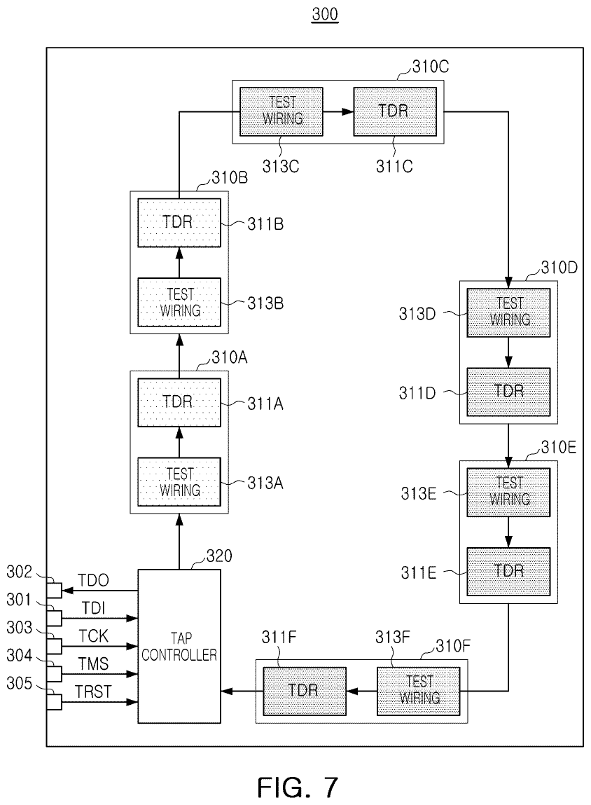

FIGS. 6 and 7 may be drawings for explaining a method for verifying whether a defect exists in a semiconductor device 300. FIG. 6 may be a drawing simply illustrating the operation of a plurality of test circuits 310A to 310F and the TAP controller 320 in the case where no defect appears in the semiconductor device 300. Meanwhile, FIG. 7 may be a drawing simply illustrating the operation of a plurality of test circuits 310A to 310F and a TAP controller 320 when a defect occurs or exists in a semiconductor device 300.

First, referring to FIG. 6, test input data TDI input through a test input pin 301 may be transmitted to a test output pin 302 through test data registers 311A to 311F controlled by a TAP controller 320. The timing at which each of the test data registers 311A to 311F stores and outputs the test input data TDI may be determined by the TAP controller 320. In some example embodiments, the TAP controller 320 may determine the timing at which each of the test data registers 311A to 311F stores and outputs the test input data TDI by referring to the test clock signal TCK.

As illustrated in FIG. 6, if there is no defect in the semiconductor device 300, the test input data TDI may be stored and output at the timing designated by the TAP controller 320 in the plurality of test circuits 310A to 310F. Accordingly, the test output data TDO detected at a predetermined or alternatively desired timing at the test output pin 302 may match the test input data TDI, and it may be determined that there is no defect in the semiconductor device 300.

On the other hand, in some example embodiments illustrated in FIG. 7, it is assumed that a defect such as cracking has occurred in the third test wiring 313C included in the third test circuit 310C. In this case, as illustrated in FIG. 7, the test input data TDI may be stored and output at the timing specified by the TAP controller 320 in the first test circuit 310A and the second test circuit 310B.

On the other hand, due to a defect occurring in the third test wiring 313C, the third test data register 311C may not be able to store and/or output the test input data TDI at the timing specified by the TAP controller 320. Accordingly, in the fourth to sixth test circuits 310D to 310F in a chain, the test input data TDI may not be stored and/or output at the timing specified by the TAP controller 320. As a result, the test output data TDO detected at the test output pin 302 at a given point in time may not match the test input data TDI, and it may be determined that a defect exists in the semiconductor device 300.

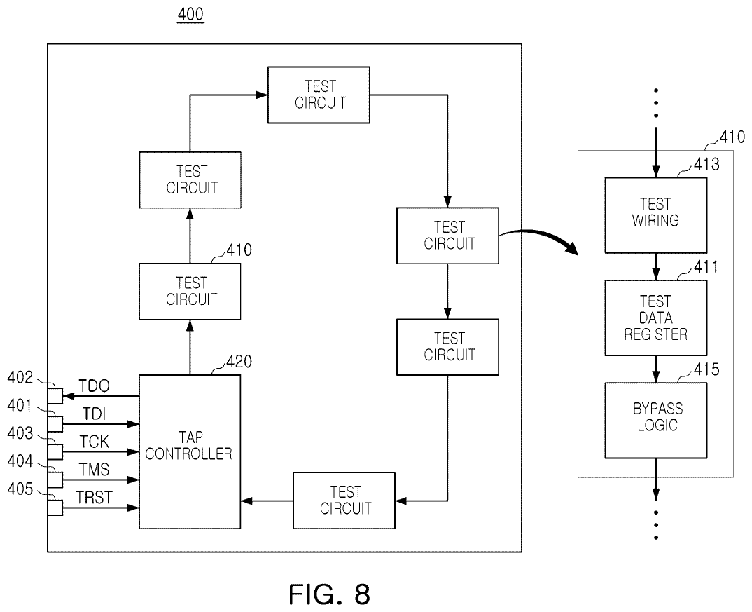

By configuring the semiconductor device 300 as described with reference to FIGS. 5 to 7, whether a defect occurs in the BEOL region where the test wirings 313A to 313F are disposed may be tested, in addition to the FEOL region where respective components of the test data registers 311A to 311F are disposed. In addition, in some example embodiments, by inserting logic that may change the transmission path of the test input data TDI into at least one of the plurality of test circuits, the region where the defect occurs may be more accurately specified. This will be described in more detail below with reference to FIG. 8.

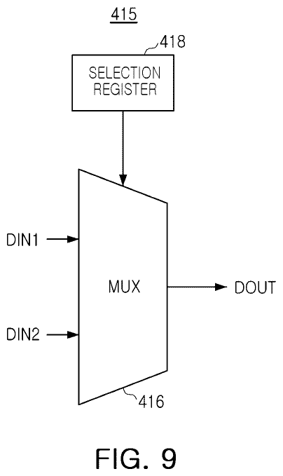

FIGS. 8 and 9 are drawings simply illustrating a semiconductor device according to some example embodiments.

First, referring to FIG. 8, a semiconductor device 400 according to some example embodiments may include a plurality of test circuits 410, a TAP controller 420, and the like. Similar to other embodiments described above, the plurality of test circuits 410 may be connected between a test input pin 401 and a test output pin 402. Each of the plurality of test circuits 410 includes a test data register 411, and the TAP controller 420 may control the operation of the test data register 411 in response to test control signals TCK, TMS and TRST received through test control pins 403 to 405.

For example, in each of the plurality of test circuits 410, the operation of storing test input data TDI in the test data register 411, the operation of outputting the test input data TDI, the timing of executing each operation, and the like may be determined by the TAP controller 420. The TAP controller 120 may be connected to external test equipment and the like via a JTAG interface, and may receive test control signals TCK, TMS and TRST.

Referring to FIG. 8, at least one of the plurality of test circuits 410 may further include a test wiring 413 and a bypass logic 415 in addition to the test data register 411. The test wiring 413 may be connected to an input terminal or an output terminal of the test data register 411. Meanwhile, the bypass logic 415 may provide an output terminal for one test circuit 410 to output data to the next test circuit 410 or the test output pin 402.

The test wiring 413 includes a plurality of test patterns and a plurality of test vias, and the plurality of test vias may connect at least some of the test patterns disposed at different heights among the plurality of test patterns. In some example embodiments, the test wiring 413 may be disposed in the BEOL region of the semiconductor device 110.

The bypass logic 415 includes a selection circuit for selecting one of the different data, and the operation of the selection circuit may be controlled by the TAP controller 420. Referring to FIG. 9, the bypass logic 415 may include a selection circuit such as a multiplexer 416, a selection register 418 for outputting a control signal for the multiplexer 416, and the like. The control signal output by the selection register 418 may be determined by the TAP controller 420.

For example, the multiplexer 416 receives the first data signal DIN1 and the second data signal DIN2, and may output one of the first data signal DIN1 and the second data signal DIN2 as an output signal DOUT based on the control signal output by the selection register 418. In some example embodiments illustrated in FIGS. 8 and 9, the first data signal DIN1 input to the multiplexer 416 may be an output of a test data register 411 included in a test circuit 410, such as a bypass logic 415. Meanwhile, the second data signal DIN2 may be an input of a test data register 411 included in a test circuit 410 such as a bypass logic 415.

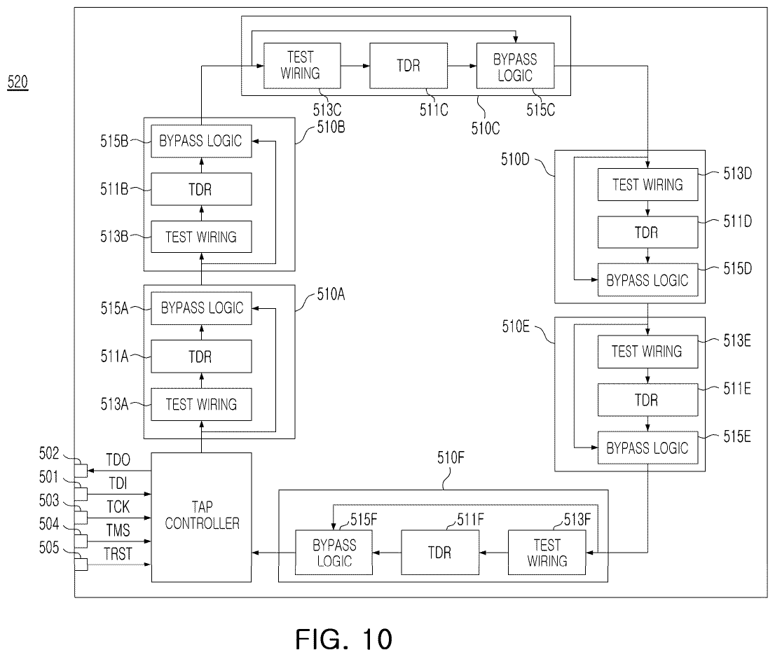

Assuming that the bypass logic 415 is included in the first test circuit 410 directly connected to the test input pin 401, the first data signal DIN1 may be an output of the test data register 411 included in the first test circuit 410, and the second data signal DIN2 may be test input data TDI input through the test input pin 401. In this manner, by including the bypass logic 415 in the test circuit 410 and changing the data transmission path between the test input pin 401 and the test output pin 402 using the bypass logic 415, the location where a defect such as cracking occurs may be more specifically identified. This will be described in more detail below with reference to FIGS. 10 to 12.

FIGS. 10 to 12 are drawings illustrating a crack detection operation in a semiconductor device according to some example embodiments.

First, referring to FIG. 10, a semiconductor device 500 according to some example embodiments may include a plurality of test circuits 510A to 510F, a TAP controller 520, and the like. The TAP controller 520 is connected to a test input pin 501, a test output pin 502, and a plurality of test control pins 503 to 505, and may control a plurality of test circuits 510A to 510F in response to test control signals TCK, TMS and TRST received through the plurality of test control pins 503 to 505. The TAP controller 520 is connected to external test equipment and the like via a JTAG interface, and may receive test control signals TCK, TMS and TRST.

Referring to FIG. 10, the plurality of test circuits 510A to 510F may include test data registers 511A to 511F, test wirings 513A to 513F, and bypass logics 515A to 515F, respectively. In some example embodiments illustrated in FIG. 10, the test wirings 513A to 513F are connected to the input terminals of the test data registers 511A to 511F in the plurality of respective test circuits 510A to 510F, and the bypass logics 515A to 515F are connected to the output terminals of the test data registers 511A to 511F, but the present inventive concepts are not necessarily limited to this form. For example, test wirings 513A to 513F may be connected between the test data registers 511A to 511F and the bypass logics 515A to 515F.

Test input data TDI input to the test input pin 501 may be transmitted to the test output pin 502 through the plurality of test circuits 510A to 510F. However, since the plurality of test circuits 510A to 510F include the bypass logics 515A to 515F, respectively, the operation of storing and outputting data by the test data registers 511A to 511F may not be executed by the TAP controller 520 in at least one of the plurality of test circuits 510A to 510F. Therefore, the data transmission path provided between the test input pin 501 and the test output pin 502 may be defined by the TAP controller 520, and the location where a defect such as cracking occurs among the test wirings 513A to 513F may be more accurately identified.

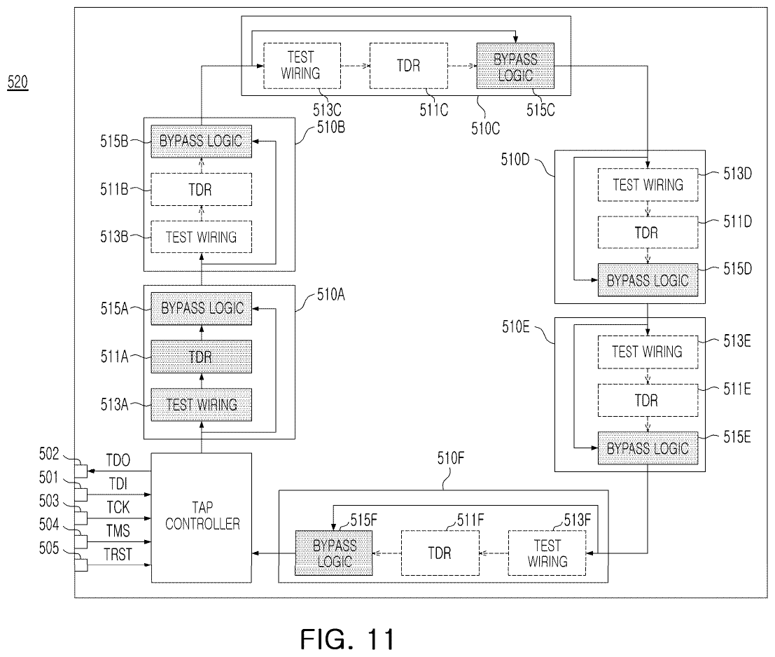

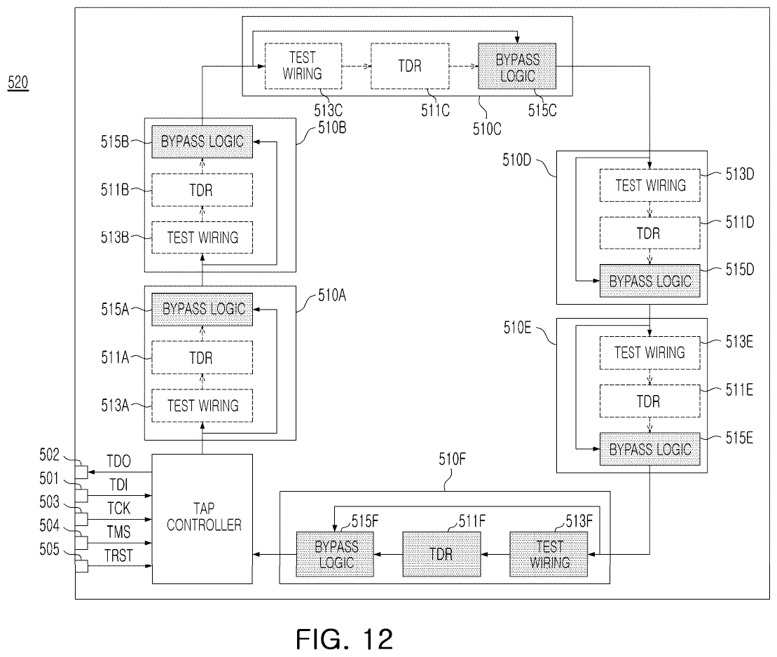

FIGS. 11 and 12 may be drawings for explaining a method of testing whether a semiconductor device 500 is defective. First, referring to FIG. 11, the test input data TDI input to the test input pin 501 may be stored in the first test data register 511A of the first test circuit 510A at the timing specified by the TAP controller 520, and may be output from the first test data register 511A at the timing specified by the TAP controller 520.

Meanwhile, the TAP controller 520 may control the bypass logics 515B to 515F in the respective second to sixth test circuits 510B to 510F so that the bypass logics 515B to 515F select input data to be transmitted to the test wirings 513B to 513F instead of the output data of the test data registers 511B to 511F. Accordingly, the output data of the first test data register 511A may be directly transmitted to the test output pin 502 by the bypass logics 515B to 515F.

In a test operation such as FIG. 11, the data transmission path may be provided by the first test circuit 510A. Accordingly, if the test output data TDO output to the test output pin 502 does not match the test input data TDI, it may be determined that there is a defect in the first test circuit 510A.

Next, in some example embodiments illustrated in FIG. 12, the bypass logics 515A to 515E in the respective first to fifth test circuits 510A to 510E may be controlled to select input data transmitted to the test wirings 513A to 513E instead of output data of the test data registers 511A to 511E. Accordingly, the test input data TDI input to the test input pin 501 may be input directly to the sixth test circuit 510F by skipping the test data registers 511A to 511E and test lines 513A to 513E of the first to fifth test circuits 510A to 510E.

The test input data TDI is stored in the test data register 511F through the test wiring 513F of the sixth test circuit 510F, and may be output from the test data register 511F to the test output pin 502 by the TAP controller 520. Therefore, in a test operation such as some example embodiments illustrated in FIG. 12, if the test output data TDO output to the test output pin 502 does not match the test input data TDI, it may be determined that there is a defect in the sixth test circuit 510F.

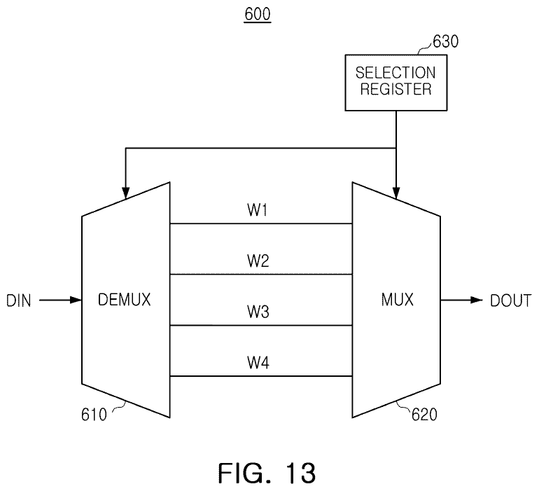

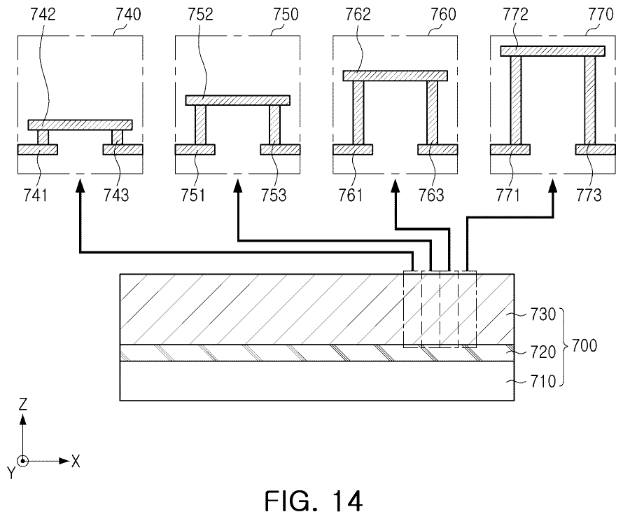

The test wirings 513A to 513F may include a plurality of test patterns disposed at different heights, and a plurality of test vias connecting the plurality of test patterns, as described above with reference to FIG. 4. In some example embodiments, the test wirings 513A to 513F may be configured so that one of two or more test patterns disposed at different heights may be selected. In this case, the layer where the defective wiring is located may be specified, and the accuracy of the defective detection may be further improved. Hereinafter, a description will be made with reference to FIGS. 13 and 14.

FIGS. 13 and 14 are drawings illustrating a crack detection operation in a semiconductor device according to some example embodiments.

FIG. 13 may be a drawing simply illustrating an example structure of a test wiring 600 included in a test circuit in a semiconductor device according to some example embodiments. Referring to FIG. 13, the test wiring 600 may include a first selection circuit 610, a second selection circuit 620, and a plurality of test wirings W1 to W4 disposed therebetween. The plurality of test wirings W1 to W4 are wirings disposed in a BEOL region, and may be disposed at different heights in a direction perpendicular to the semiconductor substrate.

The first selection circuit 610 and the second selection circuit 620 may be connected to a selection register 630 controlled by the TAP controller. The selection register 630 may control the first selection circuit 610 and the second selection circuit 620 to select one of the test wirings W1 to W4 in response to a command from the TAP controller. For example, when the first selection circuit 610, which is a demultiplexer, selects the first test wiring W1, the second selection circuit 620, which is a multiplexer, may also select the first test wiring W1.

By configuring the test wiring 600 as described with reference to FIG. 13, a data transmission path between the test input pin and the test output pin may be provided as a test wiring disposed at a specific height in the BEOL region. Accordingly, it may be tested whether there is a defect according to respective heights of the wirings disposed in the BEOL region.

The test wirings W1 to W4 connected between the first selection circuit 610 and the second selection circuit 620 may be disposed adjacent to each other within the test wiring 600. Referring to FIG. 14, a semiconductor device 700 according to some example embodiments may include a semiconductor substrate 710, a FEOL region 720, a BEOL region 730, and the like. In a direction perpendicular to the upper surface of the semiconductor substrate 710, the FEOL region 720 may be defined between the semiconductor substrate 710 and the BEOL region 730. Each of the FEOL region 720 and the BEOL region 730 may be understood with reference to the example illustrated in FIG. 4 above.

Referring to FIG. 14, the first to fourth test wirings 740 to 770 included in the BEOL region 730 may be disposed. The first to fourth test wirings 740 to 770 may include lower wirings 741, 751, 761 and 771, upper wirings 742, 752, 762 and 772, and vias 743, 753, 763 and 773, respectively.

In the first to fourth test wirings 740 to 770, the lower wirings 741, 751, 761 and 771 may be disposed at the same height. On the other hand, the upper wirings 742, 752, 762 and 772 in the first to fourth test wirings 740 to 770 are disposed at different heights, and thus the vias 743, 753, 763 and 773 may have different lengths. For example, the upper wiring 742 included in the first test wiring 740 may be disposed at the lowest position, and the upper wiring 772 included in the fourth test wiring 770 may be disposed at the highest position.

The lower wirings 741, 751, 761 and 771 included in the first to fourth test wirings 740 to 770, respectively, may be commonly connected to a selection circuit. The selection circuit is implemented with semiconductor elements included in the FEOL region 720, and the selection circuit may select only one of the upper wirings 742, 752, 762 and 772 included in the first to fourth test wirings 740 to 770. Data is transmitted to the upper wiring selected by the selection circuit, and therefore, among the upper wirings 742, 752, 762 and 772 disposed at different heights, a wiring in which a defect such as cracking has occurred may be specified.

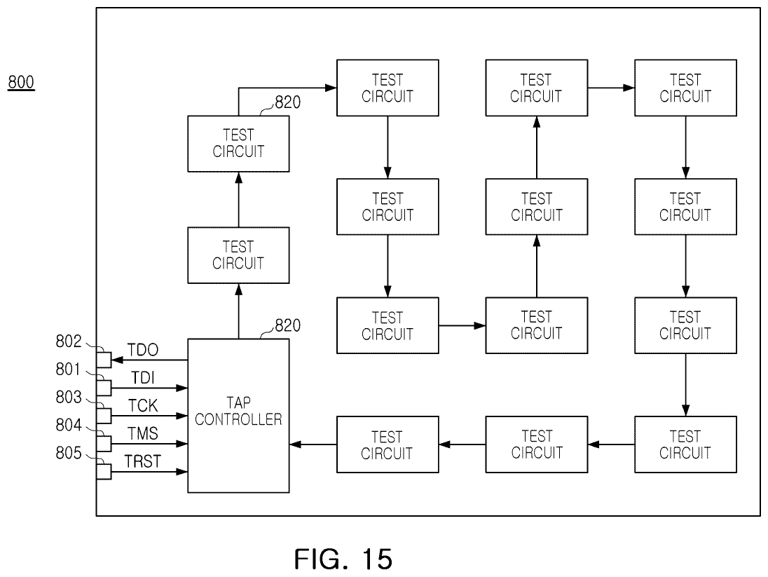

FIG. 15 is a drawing simply illustrating a semiconductor device according to some example embodiments.

Unlike the example embodiments described above, in some example embodiments illustrated in FIG. 15, a plurality of test circuits 810 connected between a test input pin 801 and a test output pin 802 may not be disposed in a loop form within a semiconductor device 800. For example, as illustrated in FIG. 3, the test circuits 110 disposed in a loop form along the boundary of the semiconductor device 100 may be connected between the pins of the semiconductor device 100 and the core logic to provide a transmission path for a data signal required for a boundary scan operation. The pins to which the test circuits 110 are connected may be pins other than the test input pin 101, the test output pin 102, and the test control pins 103 to 105.

On the other hand, in some example embodiments illustrated in FIG. 15, test circuits 810 may be freely placed at locations where it is required to monitor and test whether a defect occurs in a semiconductor device 800, regardless of boundary scan. At least some of the test circuits 810 may be placed within the core logic, in which case some of the test circuits 810 may be boundary scan cells, and the rest may be cells within the core logic. The test circuits 810 are connected in series between the test input pin 801 and the test output pin 802, and may be operated by the TAP controller 820. The TAP controller 820 may control the test circuits 810 based on the test control signals 803 to 805 received by the test control pins 803 to 805.

Each of the test circuits 810 may include a test data register capable of storing and outputting data, a test wiring connected to an input terminal and/or an output terminal of the test data register, a bypass logic for selecting one of the inputs and outputs of the test circuit 810, and the like. The configuration and operation of the test data register, the test wiring, the bypass logic and the like may be understood with reference to some example embodiments described above with reference to FIGS. 3 to 14.

As described above, a defect in the semiconductor device 800 may occur during a bonding process or the like in which the semiconductor device 800 is fixed to another semiconductor device, an interposer substrate, a package substrate, or the like. The location where a relatively strong force is applied in the bonding process may vary depending on the equipment performing the bonding process, the arrangement of pins included in the semiconductor device 800, the size of the semiconductor device 800, or the like. By arranging the test circuit 810 at the location where a relatively strong force is applied to the semiconductor device 800 in the bonding process, as illustrated in FIG. 15, defects such as cracks that may appear in the semiconductor device 800 may be verified.

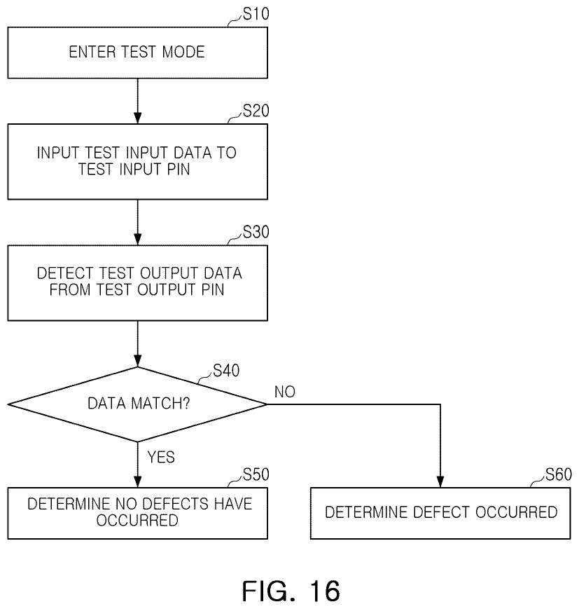

FIG. 16 is a flowchart illustrating a test operation in a semiconductor device according to some example embodiment.

Referring to FIG. 16, a test operation in a semiconductor device according to some example embodiments may begin with the semiconductor device entering a test mode (S10). In some example embodiments, the semiconductor device includes a plurality of test circuits, a TAP controller that controls the plurality of test circuits, and the like, and the plurality of test circuits may be connected between a test input pin and a test output pin.

The TAP controller may control the plurality of test circuits in response to a test mode signal and a test clock signal and execute a test operation. The TAP controller may be a finite state machine whose operating state changes according to the sequence of the test mode signal. When the semiconductor device enters the test mode, test input data may be input to the test input pin (S20).

The TAP controller may control the test circuit to store the test input data in response to the sequence of the test mode signal, or to output the stored test input data from the test circuit. A data transmission path including at least some of the test circuits may be generated between the data input pin and the data output pin by the TAP controller. When the test output data is output to the test output pin through the data transmission path, the test output data may be detected by an external device connected via a JTAG interface or the like. (S30).

The external device may determine whether the test input data input in operation S20 matches the test output data detected in operation S30 (S40). If the comparison result data in operation S40 matches, it may be determined that no defects have occurred in the test circuits included in the data transmission path (S50). For example, each of the test circuits may include a test wiring placed in the BEOL region of the semiconductor device. If the comparison result data of operation S40 matches, it may be determined that there is no defect such as cracking in the test wiring included in the data transmission path.

On the other hand, if the comparison result data of operation S40 does not match, it may be determined that a defect has occurred in at least one of the test circuits included in the data transmission path (S60). In some example embodiments, each of the test circuits may include bypass logic as described above with reference to FIG. 10. If the comparison result data of operation S40 does not match, the bypass logic of each of the test circuits may be controlled to change the data transmission path, thereby specifying the test circuit in which the defect has occurred.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

As set forth above, according to some example embodiments, a test wiring for determining whether cracking occurs may be connected to at least one of a plurality of test data registers connected between a test input pin and a test output pin. By inputting test input data to the test input pin and detecting test output data from the test output pin, it may be efficiently determined whether cracking occurs in the test wiring. If necessary, by additionally connecting bypass logic, a location in which the crack occurs may be specified. Therefore, a defect in a semiconductor device may be verified quickly and accurately.

While some example embodiments have been illustrated and described above, it will be apparent to those skilled in the art that modifications and variations could be made without departing from the scope of the present inventive concepts as defined by the appended claims.

What is claimed is:

1. A semiconductor device comprising:
a plurality of test circuits connected in series between a test input pin and a test output pin; and
a Test Access Port (TAP) controller connected to a plurality of test control pins and configured to control the plurality of test circuits in response to test control signals received by the plurality of test control pins,
wherein each of the plurality of test circuits includes a test data register,
at least one test circuit among the plurality of test circuits includes test wirings including test patterns at different heights in a first direction in a Back-End-Of-Line (BEOL) region and test vias connecting the test patterns, and
the TAP controller is configured to control the plurality of test circuits based on the test control signals so that test output data corresponding to test input data input to the test input pin is output to the test output pin.

2. The semiconductor device of claim 1, wherein each of the plurality of test circuits includes the test wirings.

3. The semiconductor device of claim 1, wherein in the at least one test circuit, the test wirings are connected to an input terminal of the test data register.

4. The semiconductor device of claim 3, wherein
the at least one test circuit includes a bypass logic connected to an output terminal of the test data register, and
the TAP controller is configured to control the bypass logic to select one of data output by the test data register and data input to the test wirings and to output the selected one.

5. The semiconductor device of claim 4, wherein each of the plurality of test circuits includes the test wirings and the bypass logic.

6. The semiconductor device of claim 1, wherein the plurality of test control pins include a Test Mode State pin, a Test Clock pin, and a Test Reset pin.

7. The semiconductor device of claim 1, wherein
the test wirings include a first test wiring in a first layer of a first height, a second test wiring in a second layer of a second height different from the first height and separated from the first test wiring, and a selection circuit configured to select one of the first test wiring and the second test wiring, and
the selection circuit is configured to connect one of the first test wiring and the second test wiring to the test data register, and the selectin circuit is configured to separate an other one of the first test wiring and the second test wiring from the test data register, in response to control of the TAP controller.

8. The semiconductor device of claim 7, wherein the selection circuit includes a demultiplexer connected to one end of each of the first test wiring and the second test wiring, and a multiplexer connected to an other end of each of the first test wiring and the second test wiring.

9. The semiconductor device of claim 1, further comprising:
a plurality of pins different from the test input pin, the test output pin, and the plurality of test control pins; and
a core logic connected to the plurality of pins through the plurality of test circuits.

10. A semiconductor package comprising:
a package substrate having wiring patterns; and
a plurality of semiconductor devices on an upper surface of the package substrate,
wherein at least one semiconductor device among the plurality of semiconductor devices includes a plurality of test control pins, a test input pin, and a test output pin connectable to a JTAG interface, and the plurality of test control pins, the test input pin, and the test output pin are electrically connected to at least one of the wiring patterns of the package substrate, and
the at least one semiconductor device includes a plurality of test data registers connected between the test input pin and the test output pin, and a test wiring connected between at least two test data registers among the plurality of test data registers and in a Back-End-Of-Line (BEOL) region.

11. The semiconductor package of claim 10, further comprising:
an interposer substrate between the package substrate and the plurality of semiconductor devices.

12. The semiconductor package of claim 10, wherein at least two of the plurality of semiconductor devices are stacked on each other in a direction perpendicular to the upper surface of the package substrate.

13. The semiconductor package of claim 10, wherein each of the plurality of semiconductor devices includes the plurality of test control pins, the test input pin, the test output pin, the plurality of test data registers, and the test wiring.

14. The semiconductor package of claim 10, wherein
the at least one semiconductor device includes a semiconductor substrate including a semiconductor material, a Front-End-Of-Line (FEOL) region defined on the semiconductor substrate and having a plurality of semiconductor elements, and the BEOL region, and
the BEOL region is defined on the FEOL region, and the test wiring is only in the BEOL region.

15. The semiconductor package of claim 14, wherein the test wiring includes a plurality of test patterns and a plurality of test vias connecting at least two test patterns at different heights among the plurality of test patterns.

16. The semiconductor package of claim 14, wherein the test wiring includes a plurality of test wirings at different heights, and the at least two test data registers are connected to each other by one of the plurality of test wirings.

17. A semiconductor device comprising:
a plurality of test circuits connected between a test input pin and a test output pin; and
a TAP controller connected to a plurality of test control pins and configured to define a data transmission path between the test input pin and the test output pin in response to test control signals received by the plurality of test control pins, the data transmission path including at least one of the plurality of test circuits.

18. The semiconductor device of claim 17, wherein each of the plurality of test circuits includes a test data register configured to store and output data in response to a command of the TAP controller, a test wiring connected to the test data register, and a bypass logic configured to determine the data transmission path in response to a command of the TAP controller.

19. The semiconductor device of claim 18, wherein in each of the plurality of test circuits, the bypass logic is configured to select one of an input and an output of the test data register.

20. The semiconductor device of claim 19, wherein in each of the plurality of test circuits, the test data register is connected between the test wiring and the bypass logic.
